(19) United States
(12) Patent Application Publication
(10) Pub. No.: US 2011/0300420 A1
(43) Pub. Date: Dec. 8, 2011

(54) TEMPERATURE CONTROLLED BATTERY PACK ASSEMBLY AND METHODS FOR USING THE SAME

(75) Inventor: Robert William Johnson, JR., Raleigh, NC (US)

(73) Assignee: Eaton Corporation

(21) Appl. No.: 12/792,357

(22) Filed: Jun. 2, 2010

(51) Int. Cl. H01M 10/50; H01L 35/34

(52) U.S. Cl. 429/62; 136/201

(57) ABSTRACT

A temperature controlled battery pack assembly includes a housing defining a battery chamber and including thermal insulation surrounding at least a portion of the battery chamber. At least one battery cell is contained in the battery chamber. The thermal insulation inhibits thermal transfer between the at least one battery cell and the surrounding environment. A thermal bridge conductor is disposed in the battery chamber and engages the at least one battery cell. The battery pack assembly further includes a thermoelectric cooler device having an inner surface and an outer surface. The thermoelectric cooler device is operable to actively transfer heat between the inner and outer surfaces using the Peltier effect. A heat sink device is in contact with or connected to the outer surface to enable thermal conduction between the outer surface and the heat sink device. The battery pack assembly includes a fan operable to force a flow of a heat transfer fluid across the heat sink device and into the environment to enable convective heat transfer between the heat sink device and the environment. The thermal bridge conductor is in contact with or connected to the inner surface to enable thermal conduction between the inner surface and the thermal bridge conductor.

### FIELD OF THE INVENTION

The present invention relates to batteries and, more particularly, to temperature controlled battery pack assemblies.

### BACKGROUND OF THE INVENTION

Exposure to elevated temperatures can significantly reduce the effective service life of batteries, such as batteries used to provide emergency backup or auxiliary power to electronic equipment that enables critical functions (e.g., computer systems, telecommunications systems and medical equipment). Information technology (IT) equipment is commonly housed in a controlled datacenter environment. While the datacenter environment has traditionally been a relatively cool environment by design, there is a trend toward higher datacenter temperatures in an effort to reduce cooling requirements and improve operating efficiency. This trend is enabled by IT equipment that is more tolerant to higher temperatures. Also, there is a shift to shorter backup times as datacenters migrate to cloud computing environments. The shorter backup times enable backup batteries to be dispersed among IT equipment on the datacenter floor. As a result, a continued rise in datacenter temperatures may adversely impact battery life in datacenters.

### SUMMARY OF THE INVENTION

According to embodiments of the present invention, a temperature controlled battery pack assembly includes a housing defining a battery chamber and including thermal insulation surrounding at least a portion of the battery chamber. At least one battery cell is contained in the battery chamber. The thermal insulation inhibits thermal transfer between the at least one battery cell and the surrounding environment. A thermal bridge conductor is disposed in the battery chamber and engages the at least one battery cell. The battery pack assembly further includes a thermoelectric cooler device having an inner surface and an outer surface. The thermoelectric cooler device is operable to actively transfer heat between the inner and outer surfaces using the Peltier effect. A heat sink device is in contact with or connected to the outer surface to enable thermal conduction between the outer surface and the heat sink device. The battery pack assembly includes a fan operable to force a flow of a heat transfer fluid across the heat sink device and into the environment to enable convective heat transfer between the heat sink device and the environment. The thermal bridge conductor is in contact with or connected to the inner surface to enable thermal conduction between the inner surface and the thermal bridge conductor.

In some embodiments, the at least one battery cell includes a plurality of battery cells.

According to some embodiments, the thermoelectric cooler device is operable to actively transfer heat from the inner surface to the outer surface using the Peltier effect to thereby cool the at least one battery cell.

The battery pack assembly may include a thermal conduction block in contact with each of the thermal bridge conductor and the inner surface to conduct heat therebetween.

The battery pack assembly may include a thermally insulative spacer between the thermal bridge conductor and the heat sink device.

In some embodiments, the housing includes an outer shell surrounding the thermal insulation, the at least one battery, the thermoelectric cooler device, the heat sink device and the fan to form a modular unit. According to some embodiments, the housing includes an inlet port and an outlet port and the fan, when operated, draws the heat transfer fluid into the housing through the inlet port, forces the heat transfer fluid across the heat sink device, and forces the heat transfer fluid out of the housing through the exit port.

In some embodiments, the at least one battery cell includes a plurality of battery cells, and the thermal bridge conductor includes a base wall supporting the plurality of battery cells and upstanding side walls integral with the base wall, the base wall and the side walls collectively defining a battery cell tray.

The battery pack assembly may include a thermoelectric cooler device controller including a control circuit operative to programmatically control a flow of electrical current to the thermoelectric cooler device and thereby control a rate of heat transfer between the at least one battery cell and the environment. In some embodiments, the control circuit is operative to control the flow of electrical current to the thermoelectric cooler device as a function of a temperature of the at least one battery cell.

According to some embodiments, the battery chamber is sealed.

In some embodiments, the housing is a modular case.

According to method embodiments of the present invention, a method for regulating a temperature of at least one battery cell includes providing a temperature controlled battery pack assembly including: a housing defining a battery chamber and including thermal insulation surrounding at least a portion of the battery chamber; at least one battery cell contained in the battery chamber, wherein the thermal insulation inhibits thermal transfer between the at least one battery cell and the surrounding environment; a thermal bridge conductor disposed in the battery chamber and engaging the at least one battery cell; a thermoelectric cooler device having an inner surface and an outer surface and being operable to actively transfer heat between the inner and outer surfaces using the Peltier effect; a heat sink device in contact with or connected to the outer surface to enable thermal conduction between the outer surface and the heat sink device; and a fan. The thermal bridge conductor is in contact with or connected to the inner surface to enable thermal conduction between the inner surface and the thermal bridge conductor. The method further includes: operating the thermoelectric cooler device to actively transfer heat between the interior and exterior surfaces using the Peltier effect; and operating the fan to force a flow of a heat transfer fluid across the heat sink device and into the environment to enable convective heat transfer between the heat sink device and the environment.

According to some embodiments, the method includes programmatically controlling a flow of electrical current to the thermoelectric cooler device and thereby controlling a rate of heat transfer between the at least one battery cell and the environment. In some embodiments, programmatically controlling the flow of electrical current to the thermoelectric cooler device includes controlling the flow of electrical current to the thermoelectric cooler device as a function of a temperature of the at least one battery cell.

Further features, advantages and details of the present invention will be appreciated by those of ordinary skill in the art from a reading of the figures and the detailed description of the preferred embodiments that follow, such description being merely illustrative of the present invention.

### BRIEF DESCRIPTION OF THE DRAWINGS

FIG. 1 is a perspective and partially schematic view of a backup power supply system including a battery pack assembly according to embodiments of the present invention.

FIG. 2 is a cross-sectional view of the battery pack assembly of FIG. 1 taken along the line 2-2 of FIG. 1.

FIG. 3 is a cross-sectional view of the battery pack assembly of FIG. 1 taken along the line 3-3 of FIG. 2.

FIG. 4 is an enlarged, fragmentary, top view of the battery pack assembly of FIG. 1.

FIG. 5 is a perspective view of a base plate forming a part of the battery pack assembly of FIG. 1.

FIG. 6 is a top view of a support bracket forming a part of the battery pack assembly of FIG. 1.

FIG. 7 is a cross-sectional view of the support bracket of FIG. 6 taken along the line 7-7 of FIG. 6.

FIG. 8 is a cross-sectional view of the support bracket of FIG. 6 taken along the line 8-8 of FIG. 6.

FIG. 9 is a cross-sectional view of the support bracket of FIG. 6 taken along the line 9-9 of FIG. 6.

FIG. 10 is a perspective view of a thermal conductor block forming a part of the battery pack assembly of FIG. 1.

FIG. 11 is a side view of a thermoelectric cooler device forming a part of the battery pack assembly of FIG. 1.

FIG. 12 is a plan view of a heat pump controller forming a part of the battery pack assembly of FIG. 1.

FIG. 13 is a schematic representation of a control circuit forming a part of the heat pump controller of FIG. 12.

FIG. 14 is a perspective view of a pair of the battery pack assemblies of FIG. 1 mounted in a chassis.

### DETAILED DESCRIPTION OF THE EMBODIMENTS OF THE INVENTION

The present invention now will be described more fully hereinafter with reference to the accompanying drawings, in which illustrative embodiments of the invention are shown. In the drawings, the relative sizes of regions or features may be exaggerated for clarity. This invention may, however, be embodied in many different forms and should not be construed as limited to the embodiments set forth herein; rather, these embodiments are provided so that this disclosure will be thorough and complete, and will fully convey the scope of the invention to those skilled in the art.

It will be understood that when an element is referred to as being “coupled” or “connected” to another element, it can be directly coupled or connected to the other element or intervening elements may also be present. In contrast, when an element is referred to as being “directly coupled” or “directly connected” to another element, there are no intervening elements present. Like numbers refer to like elements throughout. As used herein the term “and/or” includes any and all combinations of one or more of the associated listed items.

In addition, spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein the expression “and/or” includes any and all combinations of one or more of the associated listed items.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The term “programmatically” refers to operations directed and/or carried out electronically by computer modules, code, instructions and/or circuits.

The effective service life of a battery such as an auxiliary or emergency backup power battery in an uninterruptible power supply (UPS) system may depend significantly on the ambient temperature in the battery's environment. To improve battery life, the ambient temperature should be maintained in a prescribed range, typically between about 20 and 25° C. Historically, it has been a commonplace to provide cooling for electronic components in equipment. Various techniques have been employed to cool heat-producing components, such as venting, enclosure fans, heat sinks and heat pipes, for example. These devices all have a common problem, namely, they cannot reduce the temperature about the battery to below ambient temperature. As discussed above, ambient temperatures within datacenters are tending to rise to temperatures well in excess of the preferred range for enhancing battery life, so that it is now desirable to provide a mechanism to provide supplemental cooling for batteries in datacenters. The above-mentioned traditional approaches to cooling electronic equipment fail to improve the local battery ambient temperature (i.e., the ambient temperature immediately about the battery), and therefore fail to improve battery life.

Thus, there exists a need or desire to reduce the local battery ambient temperature to a temperature below the room temperature proximate or local to the battery (referred to herein as the room or datacenter ambient temperature). Known systems for cooling to below room ambient temperature include vapor phase refrigeration and Peltier cooling, for example. Vapor phase refrigeration can be relatively expensive or complex to construct or maintain. Peltier cooling provides certain design and implementation advantages (e.g., small in size and convenient), but Peltier cooling devices are typically inefficient.

In accordance with embodiments of the present invention, a battery pack assembly is configured to actively cool the local battery ambient temperature using a thermoelectric cooler (TEC) device (e.g., a Peltier device). The battery pack assembly may be configured to more efficiently utilize the TEC device. The battery pack assembly can maintain the local battery ambient temperature with a prescribed range below the room ambient temperature without consuming undue power to operate the TEC device.

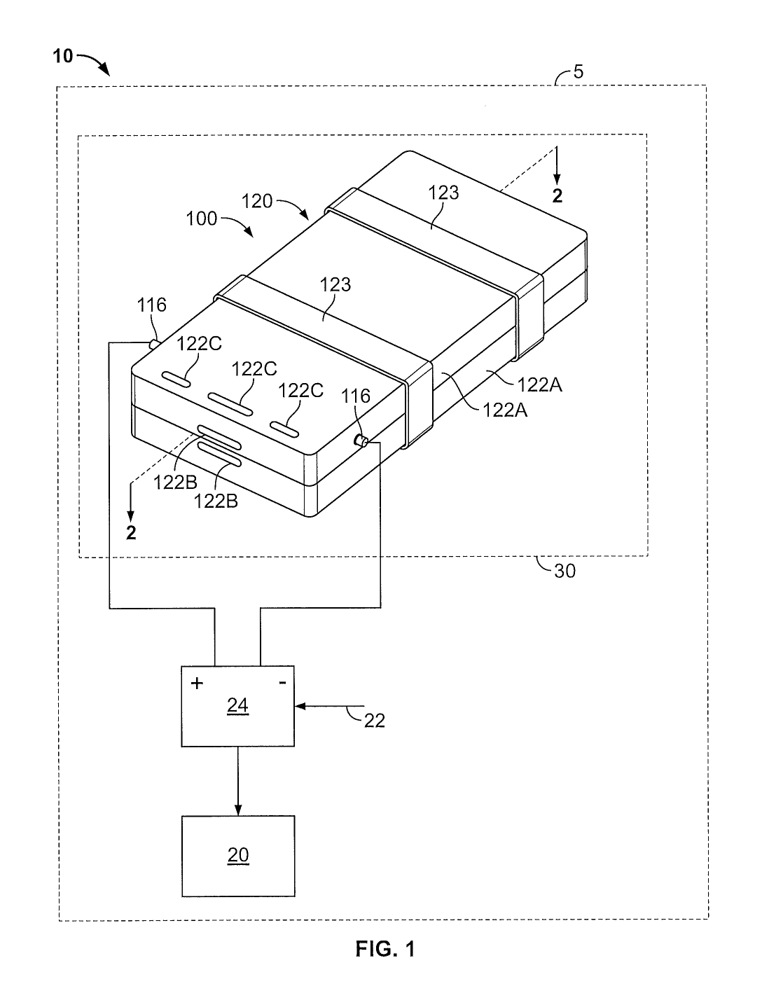

With reference to FIG. 1, a battery pack assembly 100 according to embodiments of the present invention is shown in a backup power supply system 10 in a datacenter room or cabinet 5. The system 10 includes load equipment 20, a power supply management controller or UPS circuit 24 and a battery pack assembly 100. The battery pack assembly 100 may be housed in a housing, cabinet or chassis 30 within the datacenter room 5.

The load equipment 20 and the battery pack assembly 100 are each electrically connected to the UPS circuit 24. The load equipment 20 may be, under normal operation, supplied by a line power supply 22. The line power can be routed to the load equipment 20 under the control of and/or via the power supply management controller 24. In the event of a loss of power from the line power supply 22, the power supply management controller 24 can direct power from the battery pack assembly 100 to the load equipment 20 to provide a backup or emergency power supply that enables continued operation of the load equipment 20. The battery pack assembly 100 and the power supply management controller 24 may function in the same manner as known UPSs, for example, and it will be appreciated that the battery pack assembly 100 can be used in other configurations and applications.

The load equipment 20 may be, for example, electronic equipment such as a computer server. The datacenter room 5 may be, for example, a room dedicated, at least in part, to the storage and protection of such equipment. The load equipment 20 may include IT equipment.

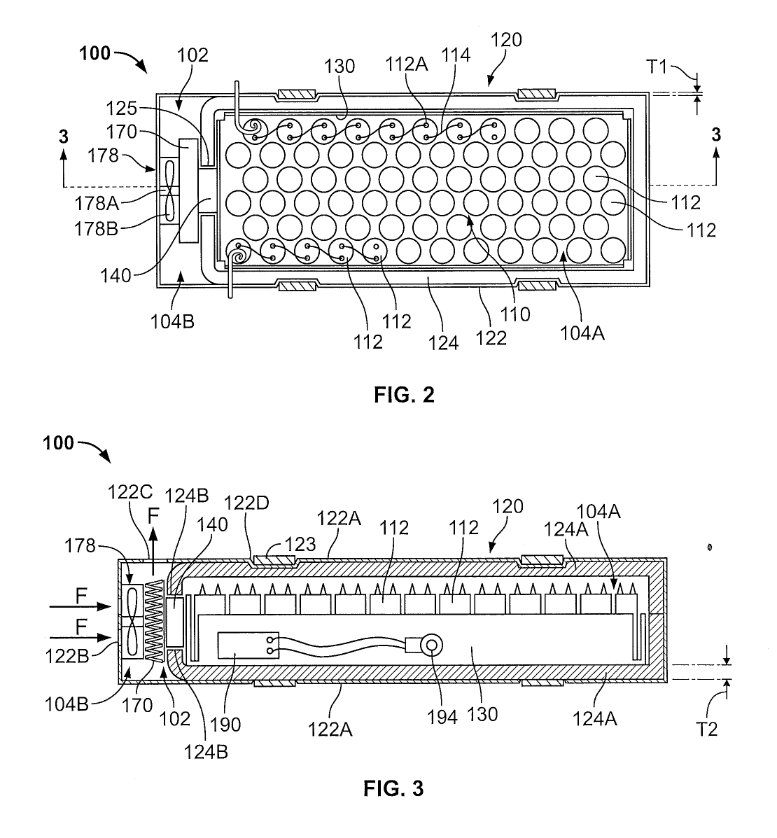

Turning to the battery pack assembly 100 in more detail and with reference to FIGS. 2-13, the battery pack assembly 100 includes a set 110 of battery cells 112, a housing or case 120 and a heat pump system 102. The case 120 defines a battery subchamber 104A within which the battery set 110 is disposed.

The battery set 110 (FIGS. 2 and 3) may include a plurality of battery cells 112 of any suitable type. In some embodiments, the battery cells 112 are rechargeable batteries. According to some embodiments, the battery cells 112 are CYCLON brand batteries. Other suitable types of batteries may include Li-Ion or VRLA batteries, for example. The terminals 112A of the battery cells 112 may be interconnected in series by leads 114, with the series terminating at opposed positive and negative battery pack terminals 116.

The case 120 (FIGS. 2 and 3) includes an outer shell 122 and thermal insulation 124. The outer shell 122 includes opposed shell parts 122A within which are seated respective insulation members 124A of the insulation 124. One or more inlet ports or vents 122B and outlet ports or vents 122C are defined in the outer shell 122. Band indentations or grooves 122D may be defined in the outer shell 122. When assembled, the case 120 can be secured closed by retention bands 123 seated in the indentations 122D. However, other mechanisms may be used to secure the case 120, such as integral latch features, fasteners or bonding. Handgrips or a handle may be formed in or mounted on the case 120 to facilitate handling.

The insulation 124 defines the battery subchamber 104A. The insulation 124 and the outer shell 122 collectively define a heat sink subchamber 104B within the outer shell 122 and opposite the battery subchamber 104A. The heat sink subchamber 104B and the battery subchamber 104A are connected by an exchange opening 125 defined in one end of the insulation 124.

The shell 122 may be formed of any suitable material, such as a metal or polymeric material. According to some embodiments, the shell 122 is formed of polyvinyl chloride (PVC). According to some embodiments, the shell 122 has a thickness T1 (FIG. 2) in the range of from about 0.05 mm to 3 mm.

The insulation 124 may be formed of any suitable material, such as a ceramic or polymeric thermal insulation material. According to some embodiments, the insulation 124 is formed of a polymeric foam such as a closed cell urethane foam. According to some embodiments, the insulation 124 has an R-value of at least 2. In some embodiments, the insulation 124 has a thickness T2 (FIG. 3) in the range of from about 6 mm to 25 mm. According to some embodiments, the insulation 124 substantially fully surrounds or envelopes the battery subchamber 104A except at the exchange opening 125.

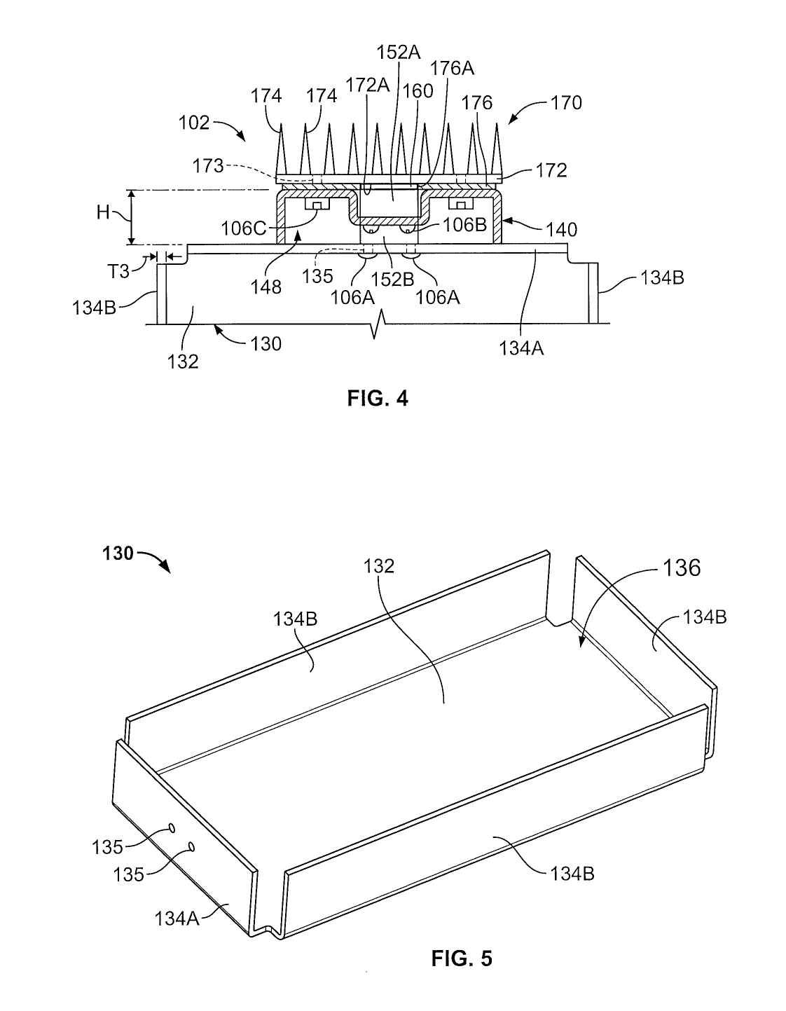

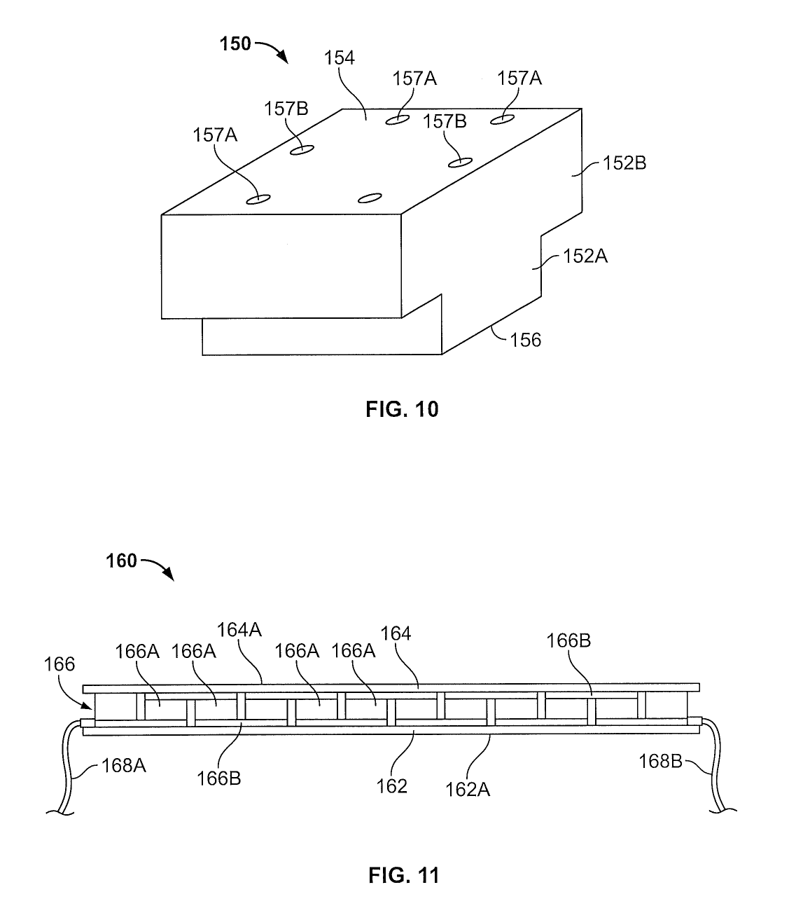

The heat pump system 102 (FIGS. 2-4) includes a thermal bridge conductor or base plate 130, a spacer or support bracket 140, a thermal conductor block 150 (FIG. 10), a thermoelectric cooler (TEC) module 160 (FIGS. 4 and 11), a heat sink device 170 (FIGS. 2-4), a pad 176 (FIG. 4), a fan 178 (FIG. 2), and fasteners (e.g., screws) 106A, 106B, 106C (FIG. 4).

The base plate 130 (FIG. 5) serves as a distributed thermal conductor that provides a connection or bridge for thermal conduction between the battery cells 112 and the thermal conductor block 150. The base plate 130 may take the form of a tray or platform having a base wall 132 and side walls 134A, 134B and defining a cavity 136. Mount holes 135 are defined in the end wall 134A. The base plate 130 may be formed of any suitable thermally conductive material such as a metal. Suitable materials for the base plate 130 may include aluminum, copper or steel, for example. The base plate 130 may be formed by metal stamping or casting, for example. According to some embodiments, the base plate 130 has a thermal conductivity of at least about 100 BTU/hr-ft-° F.) In some embodiments, the base plate 130 has a thickness T3 (FIG. 5) of from about 1 mm to 5 mm.

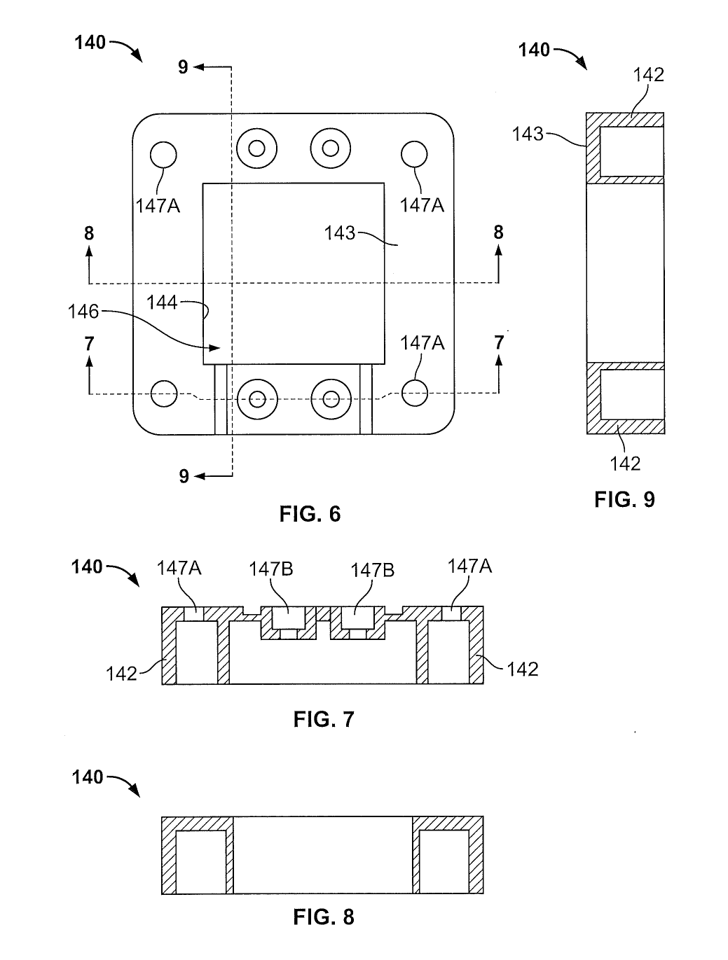

The support bracket 140 (FIGS. 6-9) has side walls 142 and a mount surface 143 defining an opening 144 and a seat 146. Screw holes 147A, 147B are provided to receive the screws 106C and 106B. The support bracket 140 may be formed of any suitable material and, according to some embodiments, is formed of a thermally insulating material. In some embodiments, the support bracket 140 is formed of a polymeric material such as ABS.

The thermal conductor block 150 (FIG. 10) may be a substantially solid block (i.e., a block having substantially no internal voids other than screw holes) defining a relatively narrow section 152A and a relatively wide section 152B. The block 150 has an inner engagement surface 154 and an outer engagement surface 156. Screw holes 157A and 157B are formed through the block 150.

The TEC module 160 (FIG. 11) may be any suitably configured thermoelectric cooler or cooling device. Generally, the TEC module 160 has first and second sides and, when a voltage is applied to the TEC module 160, the TEC module 160 creates a temperature difference between the two sides. The TEC module 160 thereby presents a relatively hot side and a relatively cold side to effect the heat transfer from the cold side to the hot side (i.e., against the temperature gradient).

According to some embodiments, for example as illustrated, the TEC module 160 includes parallel opposed inner and outer heat transfer plates 162 and 164 having opposed inner and outer engagement surfaces 162A and 164A, respectively. A Peltier layer 166 is sandwiched or interposed between the plates 162, 164. The TEC module 160 may be packaged in a pouch or cover (not shown) for protection from moisture, dust or impact.

The heat transfer plates 162, 164 are thermally conductive and typically electrically insulative. Suitable materials for the heat transfer plates 162, 164 may include a ceramic such as aluminum oxide.

The Peltier layer 166 may comprise a thermopile including a plurality of n- and p-type thermoelectric legs 166A that are thermally in parallel and connected electrically in series via electrical conductors 166B. Electrical leads 168A, 168B electrically connect the electrical conductors 166B to a direct current (DC) electrical source. The thermoelectric legs 166A may include a matrix of thermoelectric elements (e.g., pellets) such as a semiconductor (e.g., bismuth telluride). The Peltier layer 166 may be soldered to the heat transfer plates 162, 164.

Suitable constructions for the TEC module 160 will be known to those of skill in the art in view of the disclosure herein and it will be appreciated that the TEC module 160 can be configured differently than illustrated herein. Suitable TEC modules for use as the TEC module 160 may include the TEC 12705 thermoelectric cooler.

The heat sink device 170 (FIG. 4) may be constructed in any suitable configuration and of any suitable material. According to some embodiments, the heat sink device 170 is formed of a metal such as aluminum or copper. In some embodiments and as illustrated, the heat sink device 170 includes a base plate 172 having an inner engagement surface 172A. A plurality of cooling fins 174 extend from the base plate 172 opposite the engagement surface 172A.

The pad 176 (FIG. 4) may be formed of any suitable thermally insulating material. In some embodiments, the pad 176 is formed of a readily compressible, deformable material. According to some embodiments, the pad 176 is formed of cross-linked, closed cell polyolefin foam. In some embodiments, the pad 176 has a thickness in the range of from about 2 mm to 6 mm. An opening 176A is defined in the pad 176 to receive the TEC module 160.

The fan 178 (FIGS. 2 and 3) may be any suitable electric fan. The fan 178 includes a fan motor 178A and fan blades 178B.

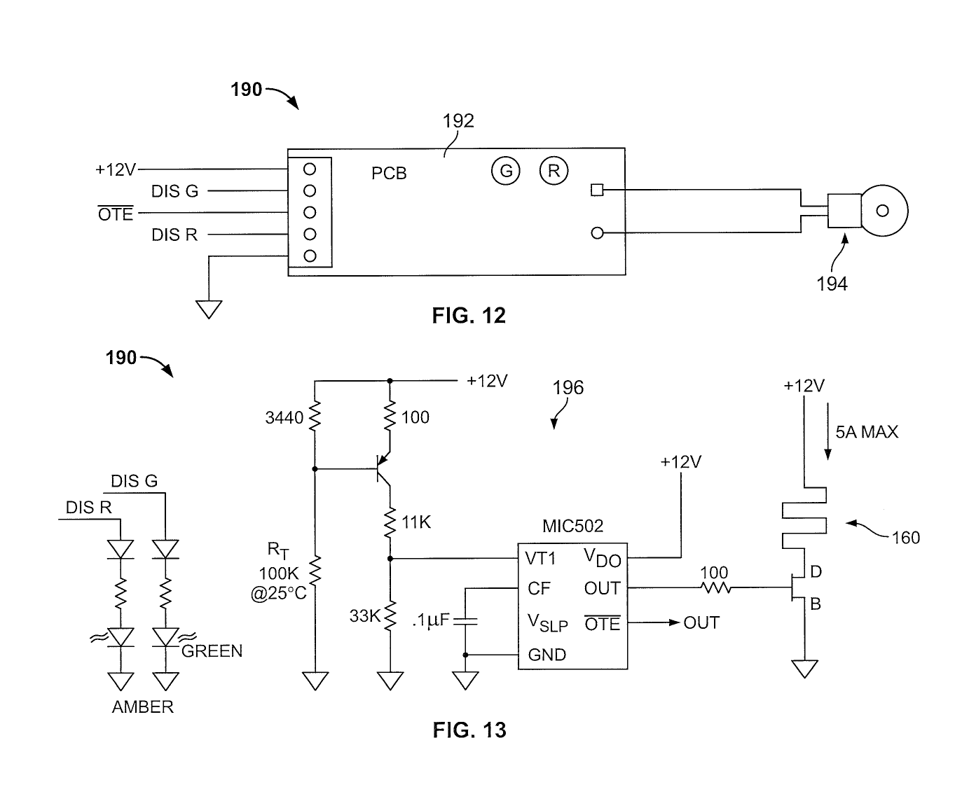

With reference to FIGS. 3, 12 and 13, the heat pump controller 190 may include a printed circuit board (PCB) 192 (FIG. 12) having a suitably configured control circuit 196 (FIG. 13) thereon. The control circuit 196 is connected to the temperature sensor 194, the TEC module 160, and the fan motor 178A (FIG. 2). The temperature sensor 194 is positioned to detect a temperature on or proximate the battery set 110. The temperature sensor 194 may be mounted on the base plate 130. The temperature sensor 194 may be a thermistor, for example. Suitable temperature sensors include the NTC 100 k@25° C. available from RTI Electronics, Inc. The PCB 192 may be located in the case 120.

The battery pack assembly 100 may be assembled as follows. The conductor block 150 is seated in the seat 146 of the support bracket 140 and secured in place by the fasteners 106B through the holes 147B and 157A as best seen in FIG. 4. The pad 176 is mounted on the mount surface 143 and the TEC module 160 is mounted in the pad opening 176A such that the inner engagement surface 162A engages the outer engagement surface 156 of the conductor block 150. The heat sink device 170 is mounted over the pad 176 and the TEC module 160 such that the engagement surface 172A engages the outer engagement surface 164A of the TEC module 160. The heat sink device 170 is secured in place by the screws 106C extending through the holes 147A and into corresponding holes 173 in the heat sink device 170. The screws 106C are tightened to provide a clamping load onto the pad 176 and the TEC module 160. In this way, reliable intimate contact between the surfaces 162A and 156 and between the surfaces 164A and 172A can be ensured to facilitate heat transfer by thermal conduction between the TEC module 160 and the conductor block 150 and the heat transfer device 170. A thermal grease can be applied to the surfaces 162A, 164A, 156, 172A to further enhance thermal conduction.

The foregoing subassembly can in turn be mounted on the end wall 134A of the base plate 130 by fastening the conductor block 150 tightly to the end wall 134A using the screws 106A through the holes 157B and the holes 135 in the end wall 134A as shown in FIG. 4. In this way, reliable intimate contact between the surface 154 and the end wall 134A can be ensured. A thermal grease can be applied between the surfaces.

Referring the FIG. 4, the side walls 142 of the support bracket 140 have a height H that spaces the base plate 172 a corresponding distance from the end wall 134A. The support bracket 140 and the end wall 134A collectively define a thermally insulating air cavity 148 (FIG. 4).

The base plate 130 with the aforedescribed subassembly of the components 140, 150, 160, 170, 176 is placed in the lower insulation member 124A (FIG. 3) such that the support bracket 140 is received in an end slot 124B (FIG. 3) in the lower insulation member 124A, which has a complementary shape and size to the outer profile of the support bracket 140. The battery set 110 is placed in the base plate 130 and the upper insulation member 124A is placed over the battery set 110 and the base plate 130 and receives an upper portion of the support bracket 140 in the complementary end slot 124B thereof. Thus, according to some embodiments, the base plate 130 and the battery set 110 are enclosed in the battery chamber 104A and the support bracket 140 extends through and substantially seals the exchange opening 125 defined by the insulation members 124A.

The outer shell members 122A are installed about the insulation members 124 to enclose the insulation members 124 and to form the heat sink subchamber 104B housing the heat sink device 170. The fan 178 can be separately mounted in the subchamber 104B to direct ambient air onto the fins 174, for example. The bands 123 are installed over the outer shell members 122.

In use, the battery pack assembly 100 is connected to the system 10 as described above with reference to FIG. 1. Under normal operation, the load equipment 20 is supplied by the line power supply 22. The battery pack assembly 100 may likewise be supplied by the line power supply 22 to maintain the stored charge of the battery set 110. Accordingly, the battery pack assembly 100 may experience prolonged periods of float or rest cycles wherein the battery set 110 does not produce great amounts of heat.

In order to improve the service life of the battery cells 112, it is desirable to maintain the local ambient battery temperature of the battery cells 112 in a prescribed target temperature range. According to some embodiments, the target temperature range is in the range of from about 20 to 25° C. In the event that the room ambient temperature exceeds the target temperature, the room ambient temperature will tend to heat the battery cells 112.

The heat pump system 102 is operated in order to fully or partially compensate for the relatively elevated room ambient temperature and thereby maintain the battery cells 112 in or proximate the target temperature range and at a temperature below the room ambient temperature. According to some embodiments, the heat pump system 102 is programmatically and automatically controlled by the heat pump controller 190.

More particularly, the heat pump controller 190 applies a voltage across the TEC module 160 so that the electrical current supplied to the Peltier layer 166 generates a temperature differential between the plates 162, 164, cools the inner plate 162 and heats the outer plate 164. The cooling of the inner plate 162 in turn cools the conductor block 150 which in turn cools the base plate 130, inducing conductive heat transfer from the battery cells 112 to the heat sink device 170 via the TEC module 160. The fan 178 is operated to draw a flow F (FIG. 3) of air (which is cooler than the heat sink device 170) from outside the case 120 through the inlet vents 122B and force the air flow F over the heat sink device 170 and out of the case 120 through the outlet vents 122C to remove heat (i.e., thermal energy) from the heat sink device 170 via convective heat transfer.

The heat pump controller 190 can control operation of the TEC module 160 based on the temperature as detected by the temperature sensor 194. The heat pump controller 190 may provide current to the TEC module 160 when the detected temperature in the battery chamber 104A exceeds the target temperature range, and may cease providing current when the detected temperature is within the target temperature range. Thus, the TEC module 160 may be cycled as needed to keep the battery chamber temperature in the desired target range. The fan 178 likewise may be actuated and deactuated based on the detected temperature (e.g., by the heat pump controller 190), or may be run continuously or periodically independently of the detected temperature.

In the foregoing manner, the temperature of the battery chamber 104A and the battery cells 112 can be cooled to and maintained at a temperature or temperatures below room ambient. This can extend the battery service life in applications or environments where the room ambient temperature is significantly higher than the optimal battery temperature. The insulation 124 insulates the battery chamber 104A from the room ambient to reduce the degree and duration of cooling required by the heat pump system 102, improving system operating efficiency. According to some embodiments, the battery chamber 104A is substantially sealed from the room ambient air to prevent or minimize convective heat transfer from the room ambient to the battery cells 112.

The battery chamber 104A may be configured to be of relatively low volume in order to provide a low surface area for unintended heat transfer between the battery cells 112 and the room, thereby permitting the effective use of a TEC module 160 having low output or efficiency.

By way of example, if the battery chamber 104A is maintained at 20° C., the room ambient is 30° C. (for an effective temperature difference of 10° C. or 10K), and the battery chamber 104A is insulated to R-2 (R=2.0 m²K/W), heat energy will be transferred to the battery chamber 104A through the case 120 at a rate of E=10K/2K*m²/W=5 watts for each square meter of surface area. This low rate of loss is within the range of heat transfer that can be generated by a low cost Peltier cooler device.

The spatially distributed base plate 130 can provide a more uniform temperature distribution across the battery set 110 and facilitate more rapid and efficient heat transfer to the heat sink device 170.

While the battery pack assembly 100 has been shown and described as including a battery set 110 including a plurality of battery cells 112, in some embodiments, only a single cell may be provided in the battery pack assembly.

While the thermal bridge conductor has been shown and described as tray-shaped base plate 130, according to some embodiments, other configurations may be employed. For example, the side walls 134A, 134B may be eliminated and/or further thermally conductive walls may be provided that extend up between and engage the battery cells 112. Other configurations for the thermal bridge conductor may include an open lattice configuration and/or a configuration wherein one or more thermal bridge conductor members extend both above and below the battery cells 112.

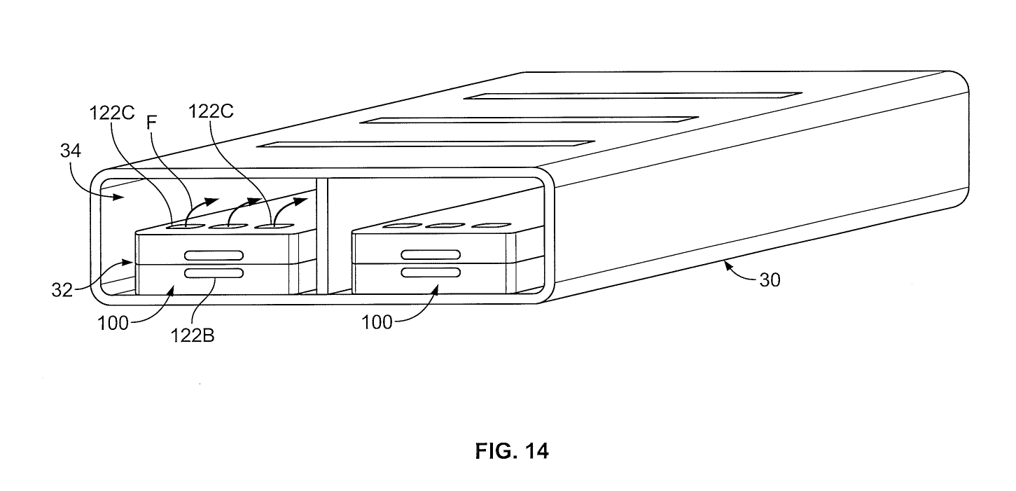

With reference to FIG. 14, the battery pack assembly 100 may be mounted in a chamber or compartment 32 of a console or chassis 30 as shown therein, for example. The compartment 32 is sized to provide a plenum 34 above the case 120 to receive the exhaust air flow F from the outlet vents 122C.

While the battery pack assembly 100 as illustrated and described constitutes a relatively compact, modular, standalone battery pack assembly unit, according to some embodiments, the case is integrated into an electronic component. For example, an electronic component (e.g., a computer server) may include an integral compartment that is insulated, vented and provided with a heat pump system corresponding to the heat pump system 102. The battery cell or cells are enclosed in the insulated compartment and cooled as described herein.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention. Therefore, it is to be understood that the foregoing is illustrative of the present invention and is not to be construed as limited to the specific embodiments disclosed, and that modifications to the disclosed embodiments, as well as other embodiments, are intended to be included within the scope of the invention.

That which is claimed is:

1. A temperature controlled battery pack assembly comprising:
a housing defining a battery chamber and including thermal insulation surrounding at least a portion of the battery chamber;
at least one battery cell contained in the battery chamber, wherein the thermal insulation inhibits thermal transfer between the at least one battery cell and the surrounding environment;
a thermal bridge conductor disposed in the battery chamber and engaging the at least one battery cell;
a thermoelectric cooler device having an inner surface and an outer surface and being operable to actively transfer heat between the inner and outer surfaces using the Peltier effect;
a heat sink device in contact with or connected to the outer surface to enable thermal conduction between the outer surface and the heat sink device; and
a fan operable to force a flow of a heat transfer fluid across the heat sink device and into the environment to enable convective heat transfer between the heat sink device and the environment;
wherein the thermal bridge conductor is in contact with or connected to the inner surface to enable thermal conduction between the inner surface and the thermal bridge conductor.

2. The battery pack assembly of claim 1 wherein the at least one battery cell includes a plurality of battery cells.

3. The battery pack assembly of claim 1 wherein the thermoelectric cooler device is operable to actively transfer heat from the inner surface to the outer surface using the Peltier effect to thereby cool the at least one battery cell.

4. The battery pack assembly of claim 1 including a thermal conduction block in contact with each of the thermal bridge conductor and the inner surface to conduct heat therebetween.

5. The battery pack assembly of claim 1 including a thermally insulative spacer between the thermal bridge conductor and the heat sink device.

6. The battery pack assembly of claim 1 wherein the housing includes an outer shell surrounding the thermal insulation, the at least one battery, the thermoelectric cooler device, the heat sink device and the fan to form a modular unit.

7. The battery pack assembly of claim 6 wherein the housing includes an inlet port and an outlet port and the fan, when operated, draws the heat transfer fluid into the housing through the inlet port, forces the heat transfer fluid across the heat sink device, and forces the heat transfer fluid out of the housing through the exit port.

8. The battery pack assembly of claim 1 wherein:
the at least one battery cell includes a plurality of battery cells; and
the thermal bridge conductor includes a base wall supporting the plurality of battery cells and upstanding side walls integral with the base wall, the base wall and the side walls collectively defining a battery cell tray.

9. The battery pack assembly of claim 1 including a thermoelectric cooler device controller including a control circuit operative to programmatically control a flow of electrical current to the thermoelectric cooler device and thereby control a rate of heat transfer between the at least one battery cell and the environment.

10. The battery pack assembly of claim 9 wherein the control circuit is operative to control the flow of electrical current to the thermoelectric cooler device as a function of a temperature of the at least one battery cell.

11. The battery pack assembly of claim 1 wherein the battery chamber is sealed.

12. The battery pack assembly of claim 1 wherein the housing is a modular case.

13. A method for regulating a temperature of at least one battery cell, the method comprising:
a) providing a temperature controlled battery pack assembly including:
a housing defining a battery chamber and including thermal insulation surrounding at least a portion of the battery chamber;
at least one battery cell contained in the battery chamber, wherein the thermal insulation inhibits thermal transfer between the at least one battery cell and the surrounding environment;
a thermal bridge conductor disposed in the battery chamber and engaging the at least one battery cell;
a thermoelectric cooler device having an inner surface and an outer surface and being operable to actively transfer heat between the inner and outer surfaces using the Peltier effect;
a heat sink device in contact with or connected to the outer surface to enable thermal conduction between the outer surface and the heat sink device; and
a fan;
wherein the thermal bridge conductor is in contact with or connected to the inner surface to enable thermal conduction between the inner surface and the thermal bridge conductor;
b) operating the thermoelectric cooler device to actively transfer heat between the inner and outer surfaces using the Peltier effect; and
c) operating the fan to force a flow of a heat transfer fluid across the heat sink device and into the environment to enable convective heat transfer between the heat sink device and the environment.

14. The method of claim 13 including programmatically controlling a flow of electrical current to the thermoelectric cooler device and thereby controlling a rate of heat transfer between the at least one battery cell and the environment.

15. The method of claim 14 wherein programmatically controlling the flow of electrical current to the thermoelectric cooler device includes controlling the flow of electrical current to the thermoelectric cooler device as a function of a temperature of the at least one battery cell.
